(19) United States
(12) Patent Application Publication
(10) Pub. No.: US 2026/0269173 A1
(43) Pub. Date: Sep. 10, 2026

(54) Charged Particle Beam System and Control Method Therefor

(71) Applicant: Hitachi High- Tech Corporation, Minato-ku, Tokyo (JP)

(72) Inventors: Anno YATSU, Tokyo (JP); Shinya KITAYAMA, Tokyo (JP); Naoki SAKAMOTO, Tokyo (JP)

(21) Appl. No.: 18/869,480

(22) PCT Filed: Jul. 19, 2022
(86) PCT No.: PCT/JP2022/028118

§ 371 Date: Nov. 26, 2024

(51) Int. Cl. H01J 37/20; H01J 37/18

(52) U.S. Cl. CPC H01J 37/20; H01J 37/185; H01J 2237/2007; H01J 2237/204

(57) ABSTRACT

To utilize an existing sample stage as it is and increase the efficiency of sample transport, the present disclosure provides a charged particle beam system including: a sample exchange chamber for exchanging a sample transported to an observation chamber; and a computer configured to control transport of the sample from the sample exchange chamber to the observation chamber, in which the sample exchange chamber includes a multi-sample table that includes an extrusion mechanism for extruding a sample and on which a plurality of samples are placeable, and a transport mechanism configured to move the multi-sample table between the sample exchange chamber and the observation chamber, and the computer executes a process of controlling the transport mechanism to transport the multi-sample table into the observation chamber, a process of controlling the extrusion mechanism to place one sample on a sample placement portion of the observation chamber from the multi-sample table transported to the observation chamber, and a process of controlling the transport mechanism to retract the multi-sample table from the observation chamber to the sample exchange chamber after placing the one sample on the sample placement portion (refer to FIG. 2).

### TECHNICAL FIELD

The present disclosure relates to a charged particle beam system and a control method therefor.

### BACKGROUND ART

An auto-loader of a scanning electron microscope (hereinafter, referred to as SEM) is a device that automates processes from attachment of a sample to transport of the sample to an observation chamber. Regarding the transport of the sample to the observation chamber, for example, PTL 1 discloses that a sample holder transport arm is configured to move in an up-down direction and a left-right direction such that the sample holder mounted on a first sample holder support portion and a second sample holder support portion is transported to a sample holder stocker. PTL 2 discloses that a plurality of samples are processed at once by setting the plurality of samples at the same height.

### CITATION LIST

### Patent Literature

PTL 1: JP2015-088237A
PTL 2: JP2013-011540A

### SUMMARY OF INVENTION

### Technical Problem

PTL 1 describes that a plurality of samples are stocked in a vacuum environment, but only a single sample held in a cartridge is transported, and PTL 1 desires to describe that the plurality of samples are transported. Therefore, each sample needs to be transported to the observation chamber, and a transport distance or a period of time for the transport is required, which is inefficient.

Meanwhile, in a sample exchange chamber of the SEM, a measurement sample needs to be attached to a sample exchange rod in the exchange chamber whenever one sample is observed. When a plurality of samples (hereinafter, multiple samples) are disposed in a stage, the size of the device (stage) increases, and the sample disposed in the stage is likely to be affected by vibration of the stage. For example, PTL 2 discloses a sample stage where sample holders on which a plurality of samples are mounted are placed. The stage is rotated after the sample holders are placed on the stage, which is a different situation from the observation of a single sample. Therefore, the size of the sample stage increases, and the sample observation itself is likely to be affected by the vibration of the stage.

Considering the above-described situation, the present disclosure proposes a technique capable of increasing efficiency of sample transport without increasing a size of a sample stage (while excluding influence of vibration of the stage).

### Solution to Problem

To achieve the above-described object, according to the present disclosure, there is provided a charged particle beam system including: an observation chamber for irradiating a sample to be observed with a charged particle beam to observe the sample; a sample exchange chamber connected to the observation chamber and for exchanging the sample transported to the observation chamber; and a computer configured to control transport of the sample from the sample exchange chamber to the observation chamber, in which the sample exchange chamber includes a multi-sample table that includes an extrusion mechanism for extruding a sample and on which a plurality of samples are placeable, and a transport mechanism configured to move the multi-sample table between the sample exchange chamber and the observation chamber, and the computer executes a process of controlling the transport mechanism to transport the multi-sample table into the observation chamber, a process of controlling the extrusion mechanism to place one sample on a sample placement portion of the observation chamber from the multi-sample table transported to the observation chamber, and a process of controlling the transport mechanism to retract the multi-sample table from the observation chamber to the sample exchange chamber after placing the one sample on the sample placement portion.

Further characteristics related to the present disclosure will be clarified from the description of the present specification and the accompanying drawing. Aspects of the present disclosure can be achieved and implemented by elements, a combination of multiple elements, the following detailed description, and the scope of the appended claims.

The description of the present specification is merely a typical example and does not limit the claims or application examples of the present disclosure by any means.

### Advantageous Effects of Invention

With the technique according to the present disclosure, efficiency of sample transport can be increased without increasing a size of a sample stage (while excluding influence of vibration of the stage).

### BRIEF DESCRIPTION OF DRAWINGS

FIG. 1 is a diagram illustrating a configuration example of a charged particle beam system 100 according to the present embodiment.

FIG. 2 is a diagram illustrating a state where a sample exchange rod 105 including a multi-sample-compatible mechanism 107 at an end portion is driven by an automatic transport mechanism to be moved to an observation chamber 101.

FIG. 3A is a top view of a sample exchange chamber 102 illustrating a state before the multi-sample-compatible mechanism 107 is inserted into the observation chamber 101.

FIG. 3B is a top view of the sample exchange chamber 102 illustrating a state where the multi-sample-compatible mechanism 107 is inserted into the observation chamber 101.

FIG. 4A is a diagram illustrating an upper surface configuration example of the multi-sample-compatible mechanism 107.

FIG. 4B is a diagram illustrating a side surface configuration example of the multi-sample-compatible mechanism 107.

FIG. 5A is a diagram illustrating a state before a banana clip 117 of an extrusion mechanism 115 is inserted into a recess portion of a sample holder 108.

FIG. 5B is a diagram illustrating a state where the banana clip 117 of the extrusion mechanism 115 is inserted into the recess portion of the sample holder 108.

FIG. 5C is a diagram illustrating a state where an extrusion mechanism driving unit 114 is operated to advance the extrusion mechanism 115 such that the sample holder 108 that holds a sample 103 is extruded.

FIG. 6A is a diagram (top view when seen from the top) illustrating a state before the banana clip 117 of the extrusion mechanism 115 is inserted into a recess portion 1081 of the sample holder 108.

FIG. 6B is a diagram (top view when seen from the top) illustrating a state where the banana clip 117 of the extrusion mechanism 115 is inserted into the recess portion 1081 of the sample holder 108.

FIG. 6C is a diagram (view when seen from the top) illustrating a state where the sample holder 108 is extracted from a stage holder receiver 104 while a sample LOCK mechanism 113 is in a fixed state.

FIG. 7 is a flowchart illustrating a sample exchange process executed by the charged particle beam system 100.

### DESCRIPTION OF EMBODIMENTS

The present embodiment discloses a technique where an auto-loader (sample transport device) is removably provided in a sample exchange chamber (removable from an observation chamber) of a charged particle beam system (for example, a SEM system) such that processes from attachment of an observation sample to the auto-loader to transport of the observation sample to an observation position (observation chamber) can be automated. Specifically, in the present embodiment, in the charged particle beam system, to provide a structure where an evacuation time required for sample exchange can be reduced, vibration caused by multiple samples can be suppressed, a transport distance required for sample exchange can be minimized, and unmanned observation can be executed, a function capable of observing multiple samples while maintaining the sample exchange chamber in a vacuum state is given to the sample exchange rod. In the present embodiment, a rotary table including multiple samples is attached to the sample exchange rod, and is extruded to an observation stage by an extrusion mechanism positioned at the center of the rotary table.

### Process of Conceiving Ideas by Present Inventors

The present inventors conducted a thorough investigation on sample transport and found that, even when a manual operation is switched to an automatic operation, a transport speed is not increased, and a throughput cannot be improved.

Accordingly, the present inventors investigated that, by adopting a sample exchange rod having a structure where a plurality of observation samples (multiple samples) can be mounted, transport and observation compatible with multiple samples can be executed without affecting a stage side (without increasing a size of the stage). The present inventors investigated that, by allowing a sample placement table (a rotary table described below) in a multi-sample-compatible mechanism to be exchangeable depending on a sample size, the maximum number of placeable samples can be changed.

As a result of the above-described investigation, the present inventors conceived the technique described in the present embodiment. Hereinafter, an embodiment of the present disclosure will be described with reference to the accompanying drawings. In the accompanying drawings, components having the same functions will be represented by the same reference numerals, and the description thereof will not be repeated.

### Configuration Example of SEM

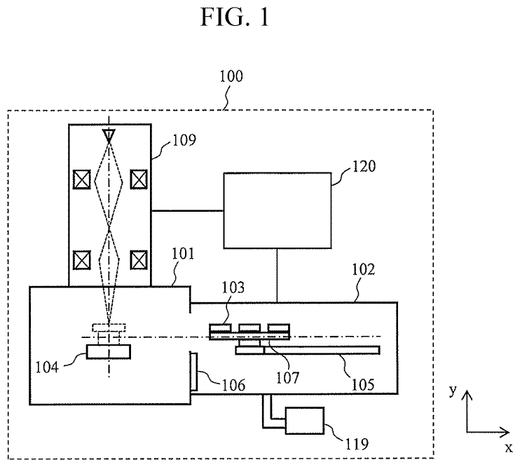

In the present embodiment, a charged particle beam system 100 where an auto-loader (sample transport device) is removably attached to a sample exchange chamber of a SEM to automate processes from setting of an observation sample to movement of the observation sample to an observation position and exchange of multiple samples will be described. FIG. 1 is a diagram illustrating a configuration example of the charged particle beam system 100 according to the present embodiment. In addition to the configuration in the drawing, an electron optical system such as a lens of the charged particle beam system 100, a control unit for scanning or the like, a unit for imaging, a vacuum pump (corresponding to an ion pump) for allowing the inside of a charged particle beam column to be in a high vacuum state, and the like are necessary but are not illustrated here.

The charged particle beam system 100 includes an observation chamber 101, a sample exchange chamber 102 that is removable from the observation chamber 101, an observation charged particle column 109 that is attached to the observation chamber 101, and a computer 120 as a control unit.

The observation chamber 101 is a chamber for irradiating a sample 103 to be observed that is placed and transported on a sample holder 108 with a charged particle beam to observe the sample 103, and includes at least an observation sample stage (not illustrated), a stage holder receiver 104, and a gate valve 106 for opening and closing the observation chamber 101. The stage holder receiver 104 is placed on the observation sample stage. The observation sample stage includes a moving mechanism (not illustrated) that adjusts a sample position for observation.

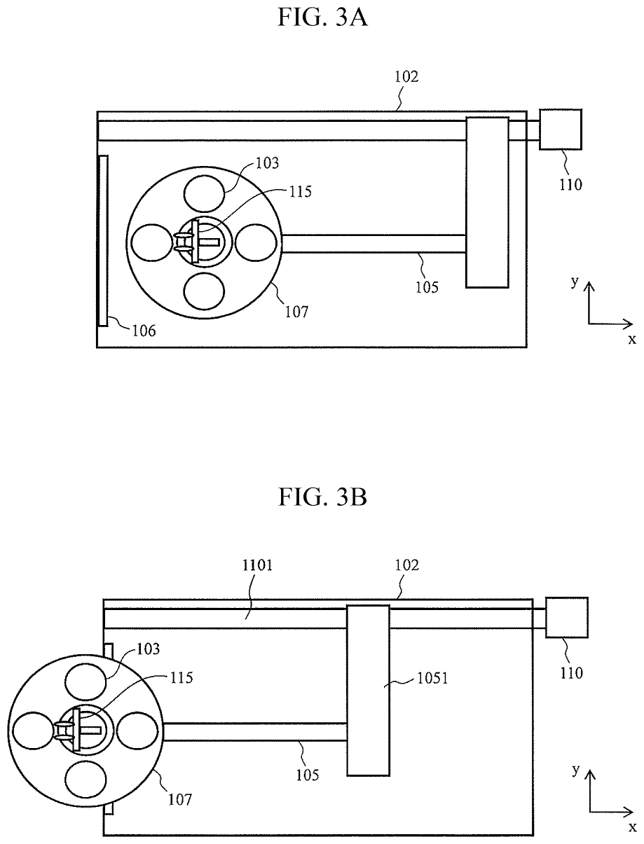

The sample exchange chamber 102 is a chamber for exchanging the sample 103 transported to the observation chamber 101, and includes a multi-sample-compatible mechanism (including a rotary table) 107 where a plurality of sample holders 108 that hold a plurality of samples 103 are placed, a sample exchange rod 105 to which the multi-sample-compatible mechanism 107 is attached, and an automatic transport mechanism 110 (refer to FIG. 3A) that moves the sample exchange rod 105 in an x-axis direction (left-right direction in the paper plane).

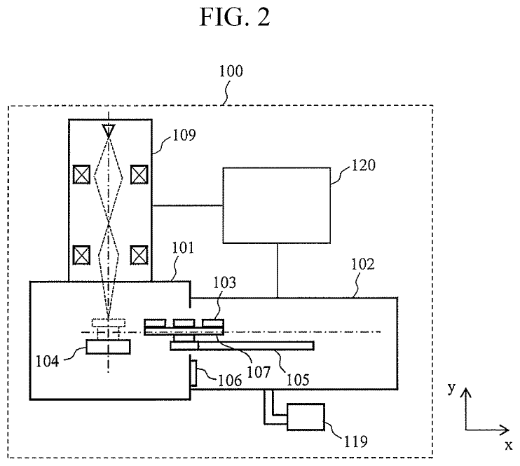

FIG. 2 is a diagram illustrating a state where the sample exchange rod 105 including the multi-sample-compatible mechanism 107 at an end portion is driven by the automatic transport mechanism 110 (not illustrated in FIG. 2; refer to FIG. 3A) to be moved to the observation chamber 101. As illustrated in FIG. 2, the plurality of samples 103 (each sample 103 is accommodated in the sample holder 108) mounted on the multi-sample-compatible mechanism 107 are inserted into the observation chamber 101 from an opening portion that is formed by opening the gate valve 106 by driving the sample exchange rod 105 in a direction of the observation chamber 101. Any one of the plurality of samples 103 is placed on the stage holder receiver 104 together with the sample holder 108. The placement of the sample holder 108 on the stage holder receiver 104 will be described below.

When observation is executed with a SEM, the sample 103 placed on the observation sample stage (the sample 103 held by the sample holder 108) is irradiated with an observation charged particle beam from an observation charged particle source in the observation charged particle column 109.

### Relationship Between Multi-Sample-Compatible Mechanism 107 and Sample Exchange Rod 105

Referring to FIGS. 3A and 3B, a relationship between the multi-sample-compatible mechanism 107 and the sample exchange rod 105 will be described. FIG. 3A is a top view of the sample exchange chamber 102 illustrating a state before the multi-sample-compatible mechanism 107 is inserted into the observation chamber 101. FIG. 3B is a top view of the sample exchange chamber 102 illustrating a state where the multi-sample-compatible mechanism 107 is inserted into the observation chamber 101. Both of FIGS. 3A and 3B illustrate a state where the sample 103 is placed on the multi-sample-compatible mechanism 107.

When the plurality of samples 103 are placed on the rotary table of the multi-sample-compatible mechanism 107, first, a roughing pump 119 described below is operated (automatically or by an operator) to open the sample exchange chamber 102 to the atmosphere while the gate valve 106 is closed. After opening the sample exchange chamber 102 to the atmosphere, the operator can remove the sample exchange chamber 102 connected to the observation chamber 101. After removing the sample exchange chamber 102 from the observation chamber 101, the operator takes out the multi-sample-compatible mechanism 107 attached to the end portion of the sample exchange rod 105 in the sample exchange chamber 102. After placing the sample holder 108 accommodating the sample 103 on the multi-sample-compatible mechanism 107, the operator attaches the multi-sample-compatible mechanism 107 to the sample exchange rod 105, and mounts the sample exchange chamber 102 on the observation chamber 101 (refer to FIG. 3A). As illustrated in FIG. 3A, the automatic transport mechanism 110 (transport motor) and the multi-sample-compatible mechanism 107 are connected via the sample exchange rod 105, and the sample exchange rod 105 advances and retracts in the x direction by the driving of the automatic transport mechanism 110 such that the multi-sample-compatible mechanism 107 connected to the sample exchange rod 105 can be advanced and retracted.

After evacuating (roughly evacuating) the sample exchange chamber 102, which will be described below while the sample exchange chamber 102 is mounted on the observation chamber 101, the gate valve 106 of the observation chamber 101 is opened. By operating the automatic transport mechanism 110 (advancing the automatic transport mechanism 110 in the direction of the observation chamber 101), the sample exchange rod 105 on which the plurality of samples 103 are placed is automatically transported to an observation position (refer to FIG. 3B). The sample holder 108 (any of the plurality of sample holders) accommodating the sample 103 is extruded by the extrusion mechanism 115 and delivered to the observation chamber 101.

### Configuration Example of Multi-Sample-Compatible Mechanism 107

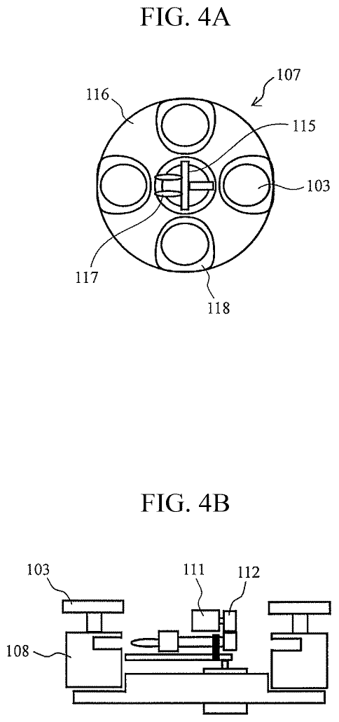

Referring to FIGS. 4A and 4B, a configuration example of the multi-sample-compatible mechanism 107 will be described. FIG. 4A is a diagram illustrating an upper surface configuration example of the multi-sample-compatible mechanism 107. FIG. 4B is a diagram illustrating a side surface configuration example of the multi-sample-compatible mechanism 107.

The multi-sample-compatible mechanism 107 includes a rotary table 116 and the extrusion mechanism 115. In the rotary table 116, a plurality of sample holder placement portions 118 that are provided in a peripheral portion and are configured with a plurality of depressions to place the sample holders 108 for holding (accommodating) the samples 103 are provided. By providing the sample holder 108 configured with the depression, a banana clip for setting the sample 103 in the related art (different from a banana clip 117 described below) is unnecessary. The depression as the sample holder placement portion 118 is an example, and any structure that can be provided and mounted without necessity to insert the sample holder 108 into the banana clip may be used.

The extrusion mechanism 115 includes the banana clip 117 that can be inserted into and removed from a recess portion provided on a side surface of the sample holder 108, a sample fixing motor 111, a gear 112, and an extrusion mechanism driving unit 114 (built-in motor) for advancing and retracting the extrusion mechanism 115. As an example of the banana clip 117, a banana clip described in JP2004-071484A can be adopted. Note that the banana clip 117 is an example, and the sample exchange rod 105 and the sample holder 108 may be connected using another method (means).

In the multi-sample-compatible mechanism 107, the extrusion mechanism 115 and the rotary table 116 at the center of the rotary table 116 are components that can be separated. Accordingly, the rotary table 116 can be removed from the sample exchange rod 105 and taken out from the sample exchange chamber 102. After placing the plurality of sample holders 108 holding the samples 103 on the sample holder placement portions 118 (depressions) of the rotary table 116, the rotary table 116 can be mounted on the sample exchange rod 105 again.

Plural types of rotary tables 116 are prepared depending on a sample size. Accordingly, the rotary table 116 that is suitable for the size of the sample 103 can be mounted (can be exchanged) on the sample exchange rod 105, and a maximum number of the samples 103 for the size of the sample 103 are constantly placeable on the rotary table 116. The rotary table 116 can be rotated by the built-in motor (not illustrated) such that the position of the sample holder placement portion 118 can be changed. Therefore, all of the samples 103 mounted on the rotary table 116 can be sequentially placed on, observed, and collected from the observation sample stage (stage holder receiver 104) of the observation chamber 101. Here, a table having a rotation function (rotary table 116) is adopted. However, a slide table, sample accommodation means having a shelf structure, or the like may be used.

### Extrusion Operation by Extrusion Mechanism 115 of Multi-Sample-Compatible Mechanism 107

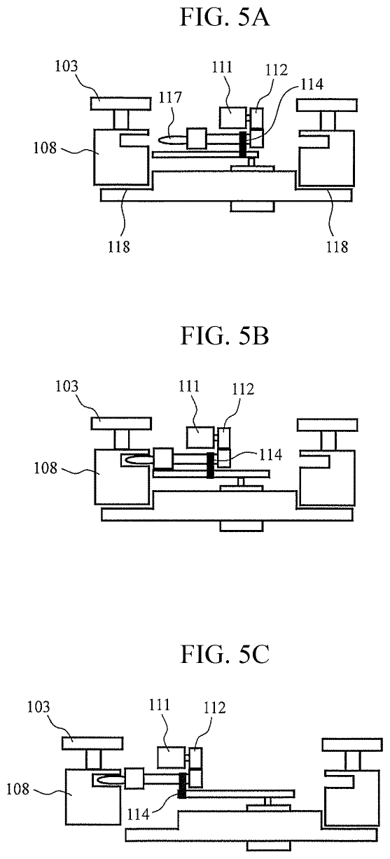

Referring to FIGS. 5A to 5C, an extrusion operation of the sample holder 108 by the extrusion mechanism 115 of the multi-sample-compatible mechanism 107 will be described.

FIG. 5A is a diagram illustrating a state before the banana clip 117 of the extrusion mechanism 115 is inserted into the recess portion of the sample holder 108. The state is continued since immediately after attaching the sample exchange chamber 102 to the observation chamber 101 until the multi-sample-compatible mechanism 107 is moved to the observation chamber 101.

FIG. 5B is a diagram illustrating a state where the banana clip 117 of the extrusion mechanism 115 is inserted into the recess portion of the sample holder 108. After moving the multi-sample-compatible mechanism 107 to the observation chamber 101, the extrusion mechanism 115 advances (advances in the direction of the sample holder 108) by the driving of the extrusion mechanism driving unit 114, and the banana clip 117 is inserted into the recess portion of the sample holder 108 (engages with the recess portion).

FIG. 5C is a diagram illustrating a state where the extrusion mechanism driving unit 114 is operated to advance the extrusion mechanism 115 such that the sample holder 108 that holds the sample 103 is extruded. After fitting the banana clip 117 into the recess portion of the sample holder 108, the extrusion mechanism 115 further advances by the driving of the extrusion mechanism driving unit 114, lifts up the sample holder 108, and places the sample holder 108 on the stage holder receiver 104 of the observation sample stage. The extrusion mechanism 115 retracts by the driving of the extrusion mechanism driving unit 114, the banana clip 117 is removed from the recess portion of the sample holder 108, and the operation of placing the sample holder 108 holding the sample 103 on the stage holder receiver 104 is completed.

### Connection Relationship Between Banana Clip 117 and Recess Portion of Sample Holder 108

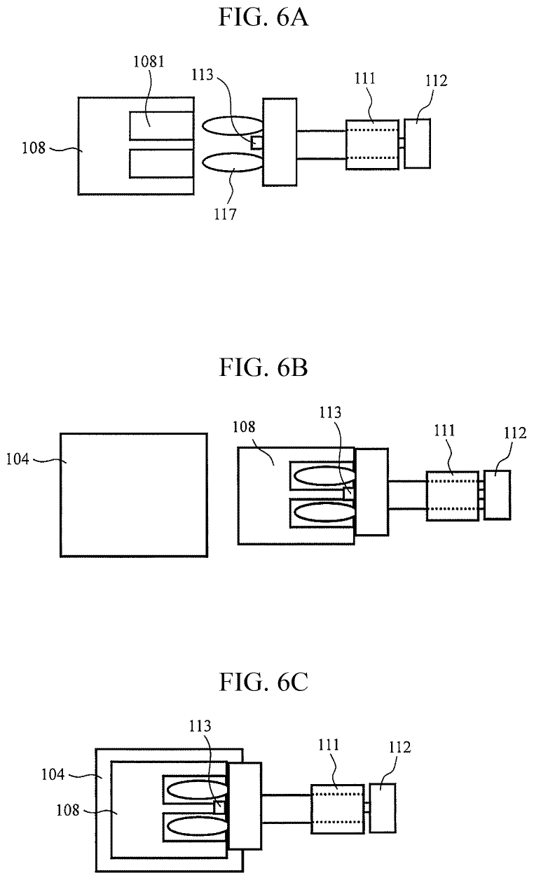

Referring to FIGS. 6A to 6C, a connection relationship between the banana clip 117 and the recess portion of the sample holder 108 will be further described.

FIG. 6A is a diagram (top view when seen from the top) illustrating a state before the banana clip 117 of the extrusion mechanism 115 is inserted into a recess portion 1081 of the sample holder 108. The extrusion mechanism 115 linearly advances (approaches the sample holder 108) by the driving of the extrusion mechanism driving unit 114 (refer to FIGS. 5A to C), and the banana clip 117 at a tip is inserted into the recess portion 1081.

FIG. 6B is a diagram (top view when seen from the top) illustrating a state (engaged state) where the banana clip 117 of the extrusion mechanism 115 is inserted into the recess portion 1081 of the sample holder 108. When the banana clip 117 enters the recess portion 1081, the sample fixing motor 111 rotates to operate a sample LOCK mechanism 113 using the gear 112. The sample 103 and the extrusion mechanism 115 can be fixed to the sample holder 108 by the sample LOCK mechanism 113. While the sample 103 and the extrusion mechanism 115 are not fixed, the sample holder 108 can be placed on the stage holder receiver 104. While the sample 103 and the extrusion mechanism 115 are fixed, the sample holder 108 placed on the stage holder receiver 104 can be extracted (taken out). More specifically, as in an example of a hooking member and a hooking member receiver illustrated in FIG. 9 of a known example of the banana clip (JP2004-071484A described above), when the sample fixing motor 111 rotates, a hooking member rotates the sample LOCK mechanism 113 using the gear 112. The sample LOCK mechanism 113 is hooked with a hooking member receiver of the sample holder 108 such that the sample holder 108 and the extrusion mechanism 115 are fixed.

FIG. 6C is a diagram (view when seen from the top) illustrating a state where the sample holder 108 is extracted from the stage holder receiver 104 while the sample LOCK mechanism 113 is in a fixed state. When the observation of the sample 103 ends, the gate valve 106 is opened (controlled by the computer 120), the sample exchange rod 105 is driven by the automatic transport mechanism 110, and the multi-sample-compatible mechanism 107 is inserted into the observation chamber 101. Next, when the extrusion mechanism 115 advances by the extrusion mechanism driving unit 114, the banana clip 117 is inserted into the recess portion 1081 of the sample holder 108. As a result, as described above, when the sample fixing motor 111 rotates to operate the sample LOCK mechanism 113 using the gear 112, the sample holder 108 and the extrusion mechanism 115 are fixed. After fixing the sample holder 108 to the extrusion mechanism 115, the extrusion mechanism 115 retracts by the extrusion mechanism driving unit 114, and the sample holder 108 is taken out from the stage holder receiver 104 and collected to the sample holder placement portion 118 of the multi-sample-compatible mechanism 107 (rotary table 116). When the collected sample holder is placed on the sample holder placement portion 118, the sample LOCK mechanism 113 is released.

### Sample Exchange Process

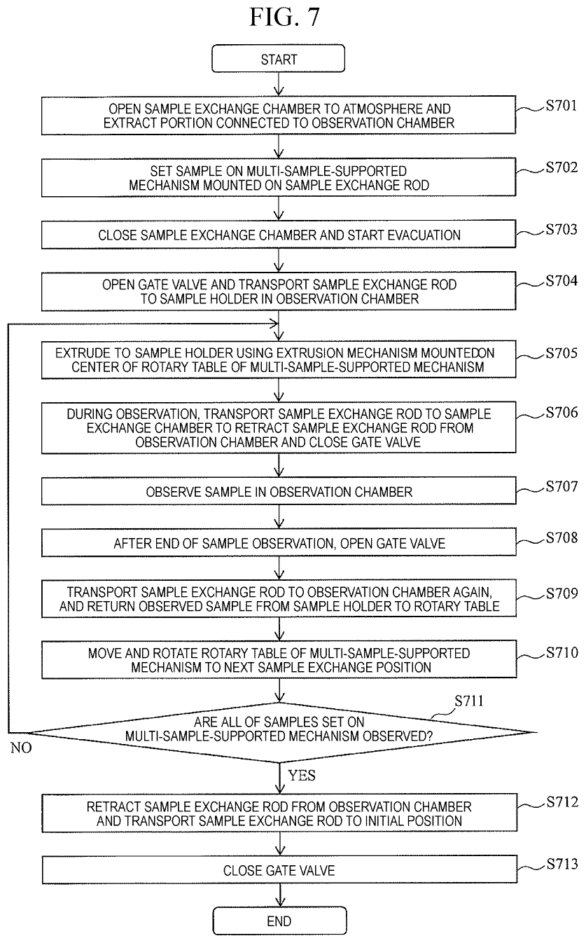

FIG. 7 is a flowchart illustrating a sample exchange process executed by the charged particle beam system 100. Here, since an automated sample exchange process will be described, an operation subject of each step in FIG. 7 is the computer 120 (control unit).

### (i) S701

When the operator (user) inputs an instruction of sample exchange to the computer (control unit) 120, the computer 120 controls the roughing pump 119 to open the sample exchange chamber 102 to the atmosphere, and displays a notification (message, sign, or the like) representing that “the sample exchange chamber 102 may be removed (may be extracted) from the observation chamber 101” on a display screen (not illustrated). After checking the notification, the operator removes the sample exchange chamber 102 from the observation chamber 101.

### (ii) S702

The operator takes out the plurality of sample holders 108 placed on the multi-sample-compatible mechanism 107 (rotary table 116) mounted on the sample exchange rod 105 from the sample exchange chamber 102, and places a plurality of sample holders 108 that hold samples 103 to be newly observed (sample exchange). When the sample size is different from the sample size of the previous observation, the operator can change the rotary table 116 in the multi-sample-compatible mechanism 107 into the rotary table 116 that is suitable for the size of the new samples.

After the sample exchanges, the operator attaches the sample exchange chamber 102 to the observation chamber 101.

### (iii) S703

When the attachment of the sample exchange chamber 102 to the observation chamber 101 is detected (for example, a sensor, a mechanism switch, or an input of an attachment completion instruction by the operator), the computer 120 controls the roughing pump 119 to roughly evacuate the inside of the sample exchange chamber 102.

### (iv) S704

After opening the gate valve 106, the computer 120 controls the driving of the automatic transport mechanism 110 to transport the sample exchange rod 105 to the stage holder receiver 104 (sample holder: not illustrated) in the observation chamber 101.

### (v) S705

The computer 120 controls the driving of the extrusion mechanism driving unit 114 to move the extrusion mechanism 115 mounted on the center of the rotary table 116 of the multi-sample-compatible mechanism 107 to the position of the stage holder receiver 104 (sample holder) and the sample holder 108 is placed on the stage holder receiver 104. When the sample holder 108 is extruded by the extrusion mechanism 115, as described above, the computer 120 rotates the sample fixing motor 111 to operate the sample LOCK mechanism 113 using the gear 112 such that the sample holder 108 and the extrusion mechanism 115 are fixed. When the sample holder 108 is placed on the stage holder receiver 104, the computer 120 releases the fixing of the sample holder 108 and the extrusion mechanism 115 using the sample LOCK mechanism 113.

### (vi) S706

After placing the sample holder 108 (one sample holder) holding the sample 103 to be observed on the stage holder receiver 104, the computer 120 controls the driving of the automatic transport mechanism 110 to retract the sample exchange rod 105 such that the sample exchange rod 105 is transported (retracted) from the observation chamber 101 to the sample exchange chamber 102. Next, the computer 120 closes the gate valve 106.

### (vii) S707

The computer 120 operates a vacuum pump (not illustrated) connected to the observation chamber 101 and mainly evacuates the inside of the observation chamber 101. Next, the computer 120 controls an electron optical system or a scanning operation of the charged particle beam system 100 to acquire an image of the sample 103 to be observed (for example, a SEM image).

### (viii) S708

When the observation of the sample 103 to be observed (required image acquisition) ends, the computer 120 opens the gate valve 106 and prepares the retraction of the observed sample 103.

### (ix) S709

The computer 120 controls the driving of the automatic transport mechanism 110 to transport the sample exchange rod 105 to the stage holder receiver 104 (sample holder 108) in the observation chamber 101 again. The computer 120 controls the driving of the extrusion mechanism driving unit 114 to move the extrusion mechanism 115 mounted on the center of the rotary table 116 of the multi-sample-compatible mechanism 107 to the position of the stage holder receiver 104 (sample holder 108), and rotates the sample fixing motor 111 to operate the sample LOCK mechanism 113 using the gear 112 such that the sample holder 108 and the extrusion mechanism 115 are fixed. Next, the computer 120 controls the driving of the extrusion mechanism driving unit 114 to retract the extrusion mechanism 115 from the position of the stage holder receiver 104 (sample holder) to the sample holder placement portion 118 of the rotary table 116, and releases the sample LOCK mechanism 113 to collect the sample holder 108 (returns the sample holder 108 to the original placement location).

### (x) S710

The computer 120 drives the built-in motor (not illustrated) that rotates the rotary table 116 of the multi-sample-compatible mechanism 107 to rotate the rotary table 116 to the next sample exchange position.

### (xi) S711

The computer 120 determines whether the observation of all of the samples 103 to be observed placed on the rotary table 116 of the multi-sample-compatible mechanism 107 is executed. The determination of whether the observation of all of the samples 103 is ended can be executed, for example, by comparing the number of samples input by the operator before the process and the number of times of execution of the observation. Alternatively, the end of the observation process may be input by the operator. Even when the observation process of all of the samples 103 did not end, the process can also be forcibly ended.

When it is determined that the observation process of the samples 103 to be observed is ended (YES in S711), the process proceeds to S712. When it is determined that the observation process of the samples 103 to be observed did not end (NO in S711), the process proceeds to S705.

### (xii) S712

The computer 120 controls the driving of the automatic transport mechanism 110 to retract the sample exchange rod 105 from the observation chamber 101, and to transport the sample exchange rod 105 to an initial position of the sample exchange chamber 102.

### (xiii) S713

The computer 120 closes the gate valve 106.

When the observed sample 103 is exchanged with another sample 103, the processes from S701 are repeatedly executed again.

### Summary

(i) In the present embodiment, the sample exchange chamber 102 of the charged particle beam system 100 includes the extrusion mechanism 115 for extruding the sample, the multi-sample-compatible mechanism 107 (multi-sample table) on which a plurality of samples are placeable, and the transport mechanism (110, 102, 105) configured to move the multi-sample-compatible mechanism 107 between the sample exchange chamber 102 and the observation chamber 101. The computer 120 controls each of the components of the charged particle beam system 100, and executes a process of controlling the transport mechanism to transport the multi-sample-compatible mechanism 107 into the observation chamber 101, a process of controlling the extrusion mechanism 115 to place one sample on the stage holder receiver 104 of the observation chamber 101 (sample placement portion of the observation chamber 101) from the multi-sample-compatible mechanism 107 transported to the observation chamber 101, and a process of controlling the transport mechanism to retract the multi-sample-compatible mechanism 107 from the observation chamber 101 to the sample exchange chamber 102 after placing one sample on the stage holder receiver 104. The computer 120 executes the observation of the sample placed on the stage holder receiver 104 by controlling the irradiation of the charged particle beam after retracting the multi-sample-compatible mechanism 107 from the observation chamber 101. As such, the samples 103 to be observed are placed on the stage holder receiver 104 of the observation chamber 101 and are observed one by one using the multi-sample-compatible mechanism 107 on which a plurality of samples can be mounted, and when the observation ends, the observed sample 103 is exchanged with another sample 103 placed on the multi-sample-compatible mechanism 107. Therefore, the sample stage can be used as it is. Accordingly, the stage size does not need to be increased, and thus adverse effects caused by vibration of the stage can be avoided. The sample 103 is placed on the stage holder receiver 104 of the observation chamber 101 from the multi-sample-compatible mechanism 107 on which the plurality of samples 103 are mounted. Therefore, when the observation of one sample 103 ends, it is not necessary to exchange the sample through external access, and thus the sample observation (sample transport) can be efficiently executed.

(ii) In the charged particle beam system 100, the gate valve 106 is provided between the observation chamber 101 and the sample exchange chamber 102. The computer 120 opens the gate valve 106 when the multi-sample-compatible mechanism 107 is transported, and closes the gate valve 106 after retracting the multi-sample-compatible mechanism 107 from the observation chamber 101 when the sample 103 is observed. During the observation, the observation chamber 101 is mainly evacuated. As such, the observation chamber 101 and the sample exchange chamber 102 can be separated by the gate valve 106. Therefore, the sample exchange chamber 102 can be removed from the observation chamber 101 to exchange a plurality of samples at once (the sample exchange chamber 102 is detachable). The vacuum degree of the observation chamber 101 can be set to be higher than the vacuum degree of the sample exchange chamber 102 by the gate valve 106. By mounting the multiple samples on the sample exchange chamber 102 and evacuating the sample exchange chamber 102, an evacuation time is not required for each of the samples, and an operating time of unmanned sample observation can be increased.

(iii) In the present embodiment, the transport mechanism (sample transport device) includes the automatic transport mechanism 110 (driving unit) and the sample exchange rod 105 (member provided between the multi-sample table and the driving unit). The multi-sample-compatible mechanism 107 is attached to the sample exchange rod 105. According to such configuration, by moving the sample exchange rod 105, the multi-sample-compatible mechanism 107 can be transported. As illustrated in FIG. 3B, the sample exchange rod 105 and the multi-sample-compatible mechanism 107 attached to the sample exchange rod 105 can be transported, for example, by the sample exchange rod 105 being connected to a rotating shaft 1101 through an intermediate member 1051 and the rotating shaft 1101 being rotated with the transport motor (automatic transport mechanism) 110.

(iv) The multi-sample-compatible mechanism 107 includes a plurality of sample holder placement portions 118 for placing a plurality of sample holders 108 each of which holds the sample 103. The extrusion mechanism 115 includes the sample LOCK mechanism 113 (sample holder fixing mechanism) configured to fix the extrusion mechanism 115 and the sample holder 108. The computer 120 controls the sample LOCK mechanism 113 to fix the extrusion mechanism 115 and the sample holder 108 when the sample holder 108 is placed on the stage holder receiver 104 (sample placement portion) of the observation chamber 101 from the multi-sample-compatible mechanism 107. The computer 120 releases the fixing of the extrusion mechanism 115 and the sample holder 108 to retract the extrusion mechanism 115 from the position of the stage holder receiver 104 when the placement of the sample holder 108 on the stage holder receiver 104 is completed. When the sample holder 108 is collected from the stage holder receiver 104 of the observation chamber 101, the computer 120 controls the sample LOCK mechanism 113 to fix the extrusion mechanism 115 and the sample holder 108, and subsequently controls the extrusion mechanism 115 to collect the sample holder 108 to the multi-sample-compatible mechanism 107. By providing the sample LOCK mechanism 113 to fix the extrusion mechanism 115 and the sample holder 108, the sample holder 108 can be stably placed on and collected from the stage holder receiver 104.

(v) The sample holder 108 includes the recess portion 1081. The extrusion mechanism 115 includes the banana clip 117 (engagement protrusion portion) that is inserted into and engages with the recess portion 1081 provided in the sample holder 108. The sample holder 108 is held by the banana clip 117 and the sample LOCK mechanism 113, and the placement on the stage holder receiver 104 and the collection from the stage holder receiver 104 are executed. By inserting the banana clip 117 into the recess portion 1081 of the sample holder 108, the placement and collection of the sample holder 108 can be more stably implemented.

(vi) When the observed sample 103 is exchanged with a non-observed sample 103, the computer 120 controls the transport mechanism to transport the multi-sample-compatible mechanism 107 to the observation chamber 101 again, controls the extrusion mechanism 115 to collect the observed sample 103, and controls the extrusion mechanism 115 again to place the non-observed sample 103 placed on the multi-sample-compatible mechanism 107 on the stage holder receiver 104. Here, the multi-sample-compatible mechanism 107 can be configured with the rotary table 116. Here, after collecting the observed sample to the sample holder placement portion 118 of the rotary table 116 where the observed sample 103 was previously placed, the computer 120 controls a built-in motor (rotation driving unit) to rotate the rotary table such that the sample holder placement portion 118 of the non-observed sample 103 is positioned at an extrusion position of the extrusion mechanism. The computer 120 controls the extrusion mechanism 115 to place the sample holder 108 holding the non-observed sample 103 on the stage holder receiver 104. As such, by using the rotary table 116, the sample exchange can be efficiently executed.

(vii) The functions of the present embodiment and each of the examples can also be implemented by a program code of software. Here, a storage medium that records the program code is provided to a system or a device, and a computer (or a CPU or an MPU) in the system or the device reads the program code stored in the storage medium. Here, the program code itself read from the storage medium implements the functions of the above-described embodiment, and the program code itself and the storage medium storing the program code configure the present disclosure. As the storage medium for supplying such the program code, for example, a flexible disk, a CD-ROM, a DVD-ROM, a hard disk, an optical disk, a magneto-optical disk, a CD-R, a magnetic tape, a non-volatile memory card, or a ROM is used.

An operating system (OS) or the like that operates on the computer may execute some or all of the actual processes based on an instruction of the program code to implement the functions of the above-described embodiment through the processes. After writing the program code read from the storage medium into a memory in the computer, a CPU or the like on the computer may execute some or all of the actual processes based on an instruction of the program code to implement the functions of the above-described embodiment through the processes.

The program code of the software implementing the functions of the embodiment and each of the examples may be distributed via a network such that the program code is stored in storage means such as a hard disk or a memory of the system or the device or in a storage medium such as a CD-RW or a CD-R, and a computer (or a CPU or an MPU) in the system or the device reads and executes the program code stored in the storage means or the storage medium during use.

The process and the technique described herein do not essentially relate to any specific device, and can also be implemented by any combination of components. Various types of general-purpose devices can be added. To execute the functions of the present embodiment and each of the examples, a dedicated device may also be constructed. Various functions can be formed by appropriately combining the plurality of components disclosed in the present embodiment and each of the examples. For example, some components may be removed from all the components disclosed in the embodiment and each of the examples, or components of different examples may be appropriately combined.

In the present disclosure, specific examples have been described. However, the examples do not limit the present disclosure from all the viewpoints and are for description purpose (to understand the technique according to the present disclosure). It can be understood by those having common knowledge in the corresponding technical field that the technique of the present disclosure can be implemented by multiple combinations of suitable hardware, software, and firmware. The described software can be implemented in a wide range of programs or script languages such as assembler, C/C++, perl, Shell, PHP, and Java (registered trademark).

In the above-described embodiment, the drawings illustrate control lines and information lines as considered necessary for explanations but do not illustrate all control lines or information lines in the products. All the configurations may be interconnected.

It is obvious that those having common knowledge in the corresponding technical field can implement other embodiments of the present disclosure considering the present embodiment and each of the examples. The specification and the specific examples are merely typical examples, and the scope and concepts of the present disclosure are indicated by the following claims.

### REFERENCE SIGNS LIST

100: charged particle beam system
101: observation chamber
102: sample exchange chamber
103: sample
104: stage holder receiver
105: sample exchange rod
106: gate valve
107: multi-sample-compatible mechanism
108: sample holder
110: automatic transport mechanism
113: sample LOCK mechanism
115: extrusion mechanism
116: rotary table
117: banana clip
118: sample holder placement portion
119: roughing pump
120: computer

1. A charged particle beam system comprising:
an observation chamber for irradiating a sample to be observed with a charged particle beam to observe the sample;
a sample exchange chamber connected to the observation chamber and for exchanging the sample transported to the observation chamber; and
a computer configured to control transport of the sample from the sample exchange chamber to the observation chamber, wherein
the sample exchange chamber includes a multi-sample table that includes an extrusion mechanism for extruding a sample and on which a plurality of samples are placeable, and a transport mechanism configured to move the multi-sample table between the sample exchange chamber and the observation chamber, and
the computer executes
a process of controlling the transport mechanism to transport the multi-sample table into the observation chamber,
a process of controlling the extrusion mechanism to place one sample on a sample placement portion of the observation chamber from the multi-sample table transported to the observation chamber, and
a process of controlling the transport mechanism to retract the multi-sample table from the observation chamber to the sample exchange chamber after placing the one sample on the sample placement portion.

2. The charged particle beam system according to claim 1, wherein
the computer executes observation of the sample placed on the sample placement portion by controlling the irradiation of the charged particle beam after retracting the multi-sample table from the observation chamber.

3. The charged particle beam system according to claim 1, wherein
a gate valve is provided between the observation chamber and the sample exchange chamber, and
the computer opens the gate valve when the multi-sample table is transported, and closes the gate valve when the sample is observed.

4. The charged particle beam system according to claim 1, wherein
the transport mechanism includes a driving unit, and a member provided between the multi-sample table and the driving unit, and
the driving unit moves the member to transport the multi-sample table connected to the member to the observation chamber and to retract the multi-sample table from the observation chamber.

5. The charged particle beam system according to claim 1, wherein
the multi-sample table includes a plurality of sample holder placement portions for placing a plurality of sample holders each of which holds the sample,
the extrusion mechanism includes a sample holder fixing mechanism configured to fix the extrusion mechanism and the sample holder, and
the computer controls the sample holder fixing mechanism to fix the extrusion mechanism and the sample holder when the sample holder is placed on the sample placement portion of the observation chamber from the multi-sample table, and releases fixing of the extrusion mechanism and the sample holder to retract the extrusion mechanism from a position of the sample placement portion when the placement of the sample holder on the sample placement portion is completed.

6. The charged particle beam system according to claim 5, wherein
when collecting the sample holder from the sample placement portion of the observation chamber, the computer controls the sample holder fixing mechanism to fix the extrusion mechanism and the sample holder, and controls the extrusion mechanism to collect the sample holder to the multi-sample table.

7. The charged particle beam system according to claim 6, wherein
the extrusion mechanism includes an engagement protrusion portion that is inserted into and engages with a recess portion provided in the sample holder, holds the sample holder with the engagement protrusion portion and the sample holder fixing mechanism, and executes the placement on the sample placement portion and the collection from the sample placement portion.

8. The charged particle beam system according to claim 1, wherein
when the observed sample is exchanged with a non-observed sample, the computer controls the transport mechanism to transport the multi-sample table to the observation chamber again, controls the extrusion mechanism to collect the observed sample, and controls the extrusion mechanism to place the non-observed sample placed on the multi-sample table on the sample placement portion.

9. The charged particle beam system according to claim 8, wherein
the multi-sample table is configured with a rotary table, and
after collecting the observed sample to a portion of the rotary table where the observed sample was previously placed, the computer controls a rotation driving unit to rotate the rotary table such that a portion where the non-observed sample is placed is positioned at an extrusion position of the extrusion mechanism, and controls the extrusion mechanism to place the non-observed sample on the sample placement portion.

10. The charged particle beam system according to claim 1, wherein
the sample exchange chamber is detachably connected to the observation chamber.

11. A control method for a charged particle beam system including an observation chamber for irradiating a sample to be observed with a charged particle beam to observe the sample, a sample exchange chamber connected to the observation chamber and for exchanging the sample transported to the observation chamber, and a computer configured to control transport of the sample from the sample exchange chamber to the observation chamber, the control method comprising:
allowing the computer to control a transport mechanism to transport a multi-sample table from the sample exchange chamber to the observation chamber, the multi-sample table including an extrusion mechanism for extruding a sample and on which a plurality of samples are placeable;
allowing the computer to control the extrusion mechanism to place one sample on a sample placement portion of the observation chamber from the multi-sample table transported to the observation chamber, and
allowing the computer to control the transport mechanism to retract the multi-sample table from the observation chamber to the sample exchange chamber after placing the one sample on the sample placement portion.

12. The control method for the charged particle beam system according to claim 11, wherein
the computer opens a gate valve provided between the observation chamber and the sample exchange chamber to transport the multi-sample table from the sample exchange chamber to the observation chamber, and closes the gate valve after retracting the multi-sample table from the observation chamber when the sample is observed.

13. The control method for the charged particle beam system according to claim 11, wherein
the multi-sample table includes a plurality of sample holder placement portions for placing a plurality of sample holders each of which holds the sample,
the extrusion mechanism includes a sample holder fixing mechanism configured to fix the extrusion mechanism and the sample holder, and
the control method further comprises:
allowing the computer to control the sample holder fixing mechanism to fix the extrusion mechanism and the sample holder such that the sample holder is held by the extrusion mechanism and to place the sample holder on the sample placement portion of the observation chamber from the multi-sample table; and
allowing the computer to release fixing of the extrusion mechanism and the sample holder to retract the extrusion mechanism from a position of the sample placement portion after the placement of the sample holder on the sample placement portion is completed.

14. The control method for the charged particle beam system according to claim 13, the control method further comprising:
allowing the computer to control the sample holder fixing mechanism to fix the extrusion mechanism and the sample holder, and to control the extrusion mechanism to collect the sample holder to the multi-sample table.

15. The control method for the charged particle beam system according to claim 11, the control method further comprising:
allowing the computer to control the transport mechanism to transport the multi-sample table to the observation chamber again; and
allowing the computer to control the extrusion mechanism to collect the observed sample, and to control the extrusion mechanism again to place the non-observed sample placed on the multi-sample table on the sample placement portion.

16. The control method for the charged particle beam system according to claim 15, wherein
the multi-sample table is configured with a rotary table, and
after collecting the observed sample to a portion of the rotary table where the observed sample was previously placed, the computer controls a rotation driving unit to rotate the rotary table such that a portion where the non-observed sample is placed is positioned at an extrusion position of the extrusion mechanism, and controls the extrusion mechanism to place the non-observed sample on the sample placement portion.
